(19) United States
(12) Patent Application Publication
(10) Pub. No.: US 2004/0124857 A1
(43) Pub. Date: Jul. 1, 2004

(54) Capacitive measurement device

(76) Inventors: Pascal Jordana, La Queue-En-Brie (FR); Claude Launay, Champigny (FR); Daniel Le Reste, Ferrieres-En-Brie (FR); William Pancirolii, Prunay-En-Yvelines (FR); Joaquim Da Silva, St Jean-De-Brayes (FR); Philippe Parbaud, La Ferte-St-Aubin (FR)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/432,806

(22) PCT Filed: Nov. 20, 2001
(86) PCT No.: PCT/FR01/03632

(30) Foreign Application Priority Data
Nov. 23, 2000 (FR) 00-15119
Nov. 23, 2000 (FR) 00-15120
Nov. 23, 2000 (FR) 0015121
Nov. 23, 2000 (FR) 00-15123
Nov. 23, 2000 (FR) 0015127

(51) Int. Cl. G01R 27/26

(52) U.S. Cl. 324/679

(57) ABSTRACT

The invention concerns a measurement device comprising at least a measuring probe (10), means (30) for sequentially applying a controlled supply voltage between the measuring probe (10) and a reference element (20) and means (50) for integrating the electric loads accumulated on the measuring probe (10). The invention is characterised in that it further comprises means (60) for correcting the integrating stage (50) input offset.

The present invention relates to the field of sensors.

More precisely, the present invention relates to a measurement device utilizing an indirect measurement of permittivity between two electrically conducting bodies respectively forming a measurement probe and a reference element, for example a reference probe.

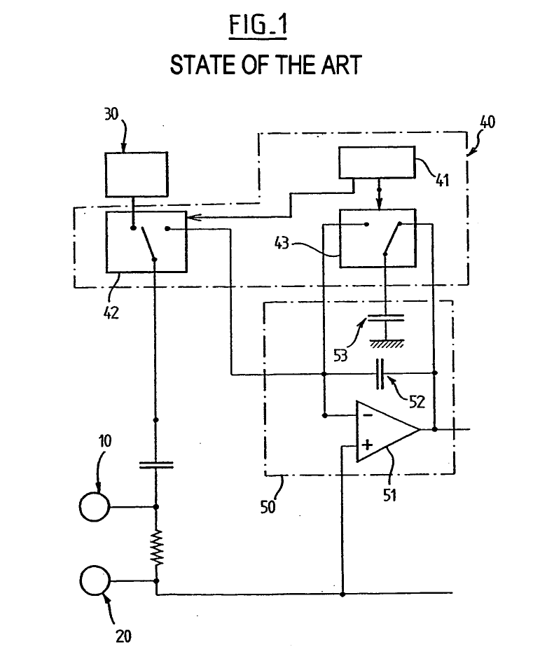

A device whose basic structure is shown diagrammatically in the appended FIG. 1 is described in document WO-0025098.

This device comprises two electrically conducting bodies respectively constituting a measurement probe 10 and a reference probe 20, electrical supply means 30 able to deliver a DC electric voltage of controlled amplitude, an integrator stage 50 comprising a capacitance switching system 53 and operating means 40 suitable for defining cyclically, at a controlled frequency, a set of two sequences:

a first sequence T1 in the course of which the electrical supply means 30 are linked to the measurement probe 10 so as to apply an electric field between the measurement probe 10 and the reference probe 20 and accumulate electric charge on the measurement probe 10,

then a second sequence T2 in the course of which the electrical supply means 30 are disconnected from the measurement probe 10 and the latter is linked to a summation point of the integrator stage 50 so as to transfer charge into the integrator stage 50 and obtain at the output of the latter a signal representative of the permittivity existing between the measurement probe 10 and the reference probe 20.

More precisely still, according to document WO-0025098, the integrator stage 50 comprises an operational amplifier 51, a first integration capacitor 52 arranged in feedback mode with this amplifier 51 and a second capacitor 53 switched between the output and the input of the operational amplifier 51 at the tempo of the sequences driven by the operating means 40, so that in the steady balance state, there is obtained at the output of the operational amplifier 51, a balance voltage equal to: −E.Cs/C53, in which relation −E designates the amplitude of the voltage across the terminals of the electrical supply means 30, and Cs and C53 respectively designate the values of the capacitances defined between the measurement probe 10 and the reference probe 20 on the one hand and the second switched capacitor 53 on the other hand.

The switching of the electrical supply means 30 and of the second capacitor 53 is provided for by inverter on/off switches 42, 43 driven by a time base 41.

The manner of operation of this known device is essentially as follows:

Let us assume that at the outset the integration capacitor C52, the switching capacitor C53 and the capacitor Cs formed between the measurement probe 10 and the reference probe 20 are each fully discharged, i.e.

QC52=0

QC53=0, and

QCs=0.

During the first sequence T1, the capacitor Cs is charged under the supply voltage delivered by the module 30, which here is assumed equal to −E.

At the end of the sequence T1, we therefore have:

QCs=−E.Cs

QC52=0.

QC53=0.

In the course of the next sequence T2, the charge is transferred from Cs to C52; i.e. the charge being preserved and Cs and C53 being linked to the inverting input of the operational amplifier 51 of zero virtual impedance: −E.Cs=Vs2.C52, calling Vs2 the output voltage of the operational amplifier 51 during the sequence T2.

In the course of the next sequence T1, the two capacitors C52 and C53 are placed in parallel. We then have:

$$\begin{matrix}\begin{matrix}Vs = Vs2 . C52 / ( C52 + C53 ) \\ = QC53 / C53 = QC52 / C52 , i . e .\end{matrix} \\ \begin{matrix}QC53 = [ Vs2 . C52 / ( C52 + C53 ) ] \cdot C53 \\ = [ Vs2 / ( 1 + C53 / C52 ) \cdot C53\end{matrix} \\ i . e . if C52 = nC53 \&RightSkeleton; C53 \\ QC53 ≃ Vs2 \cdot C53 .\end{matrix}$$

At the next sequence T2, the charge contained in C53 opposes that of Cs. The remaining part of the charge of Cs is transferred to C52, etc.

The output voltage Vs, at the output of the operational amplifier 51 increases progressively up to a voltage Vs balance=QC53/C53 such that

QC53=Vs balance.C53=−E.Cs.

Thus after x iterations the device reaches a state of balance on the summation point. The charge QC53 of C53 compensates for the charge of the probe Cs.

As soon as a variation in capacitance Cs is detected, the additional charge (or the loss of charge) on Cs charges (or discharges) the capacitor C52.

Thus in the steady state the switching capacitor C53 balances the variations in charge of the probe Cs.

The aim of the present invention is now to propose a novel device exhibiting superior performance to that of the known devices.

More precisely still, the aim of the present invention is to compensate for any drifting due for example to temperature, to humidity, or to low-frequency electrical disturbances generated by capacitive coupling, in the earlier known devices.

This aim is achieved within the framework of the present invention by virtue of a device comprising at least one measurement head including at least one measurement probe, means able sequentially to apply a controlled supply voltage between the measurement probe and a reference element and means able to integrate the electric charge accumulated on the measurement probe, characterized in that it furthermore comprises means able to provide an offset correction of the input of the integrator stage.

According to another advantageous characteristic of the present invention, the device furthermore comprises a differentiator stage receiving on its respective inputs signals representative of the measurement head output for a similar offset correction, but different controlled supply voltages.

According to another advantageous characteristic of the present invention, the device comprises two measurement heads, and the signals applied to the differential stage originate respectively from the output of the integrator stages of these two measurement heads.

According to another advantageous characteristic of the present invention, the two measurement probes belonging respectively to the aforesaid two measurement heads are situated in tight proximity and placed in the same medium.

According to another advantageous characteristic of the present invention, as an option the device may comprise a single measurement head and storage means able to store the signal representative of the output from the measurement head for a given offset correction and a controlled supply voltage, so as to allow the differentiator stage to then compare the signal thus stored with the signal obtained at the output of the measurement head for a similar offset correction, but a different controlled supply voltage.

According to another advantageous characteristic of the present invention, the offset correction of the integrator stage is carried out with the aid of a circuit comprising a capacitor supplied via an adjustable voltage.

According to another advantageous characteristic of the present invention, the device furthermore comprises means able to slave the offset correction to the output signal from the integrator stage.

According to another aspect, the present invention relates to a device comprising at least one measurement head comprising at least one measurement probe, means able sequentially to apply a controlled supply voltage between the measurement probe and a reference element and means able to integrate the electric charge accumulated on the measurement probe, characterized in that it comprises means able to place different respective probes successively in circuit on the input of the integrator stage.

According to another aspect the present invention relates to a device comprising at least one measurement head comprising at least one measurement probe, means able sequentially to apply a controlled supply voltage between the measurement probe and a reference element and means able to integrate the electric charge accumulated on the measurement probe, characterized in that the electrical supply means are suitable for applying successive controlled variable voltages to the measurement probe and that the device furthermore comprises means for analyzing the trend of the signals at the output of the integrator stage as a function of the supply voltages applied.

Other characteristics, aims and advantages of the present invention will become apparent on reading the detailed description which follows and with regard to the appended drawings given by way of nonlimiting examples and in which:

FIG. 1 described previously diagrammatically represents a device in accordance with the state of the art disclosed in document WO-0025098,

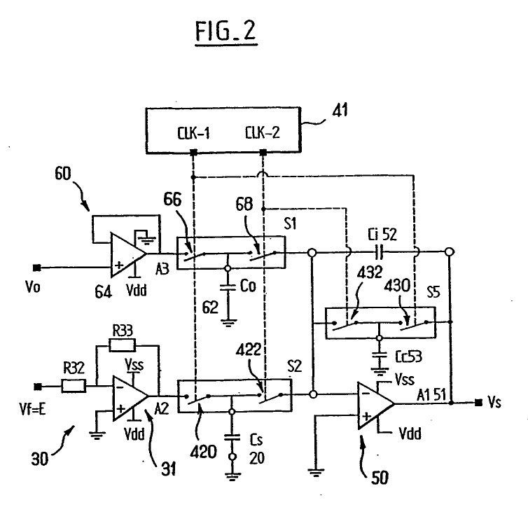

FIG. 2 represents a basic circuit in accordance with the present invention comprising offset correction means,

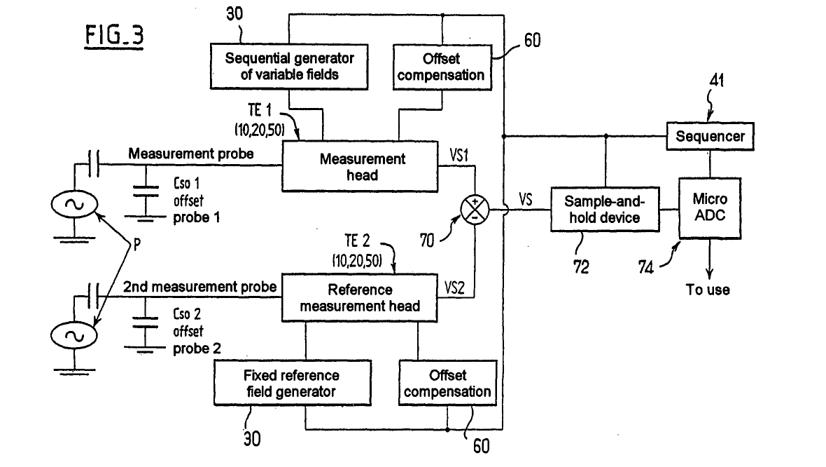

FIG. 3 represents the basic structure of a device in accordance with the present invention comprising two measurement heads,

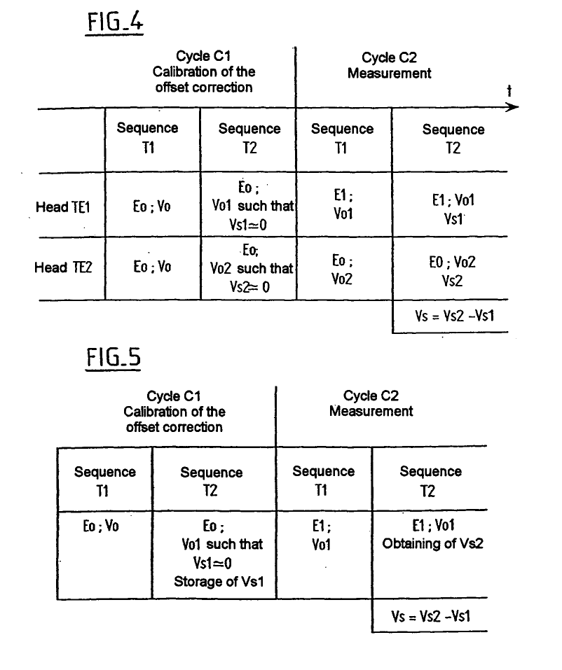

FIG. 4 diagrammatically represents a timing chart of the operation of a device in accordance with the present invention, comprising two measurement heads used in differential mode,

FIG. 5 represents a similar timing chart for the operation of a device in accordance with the present invention, comprising a single measurement head with storage of the output of the latter,

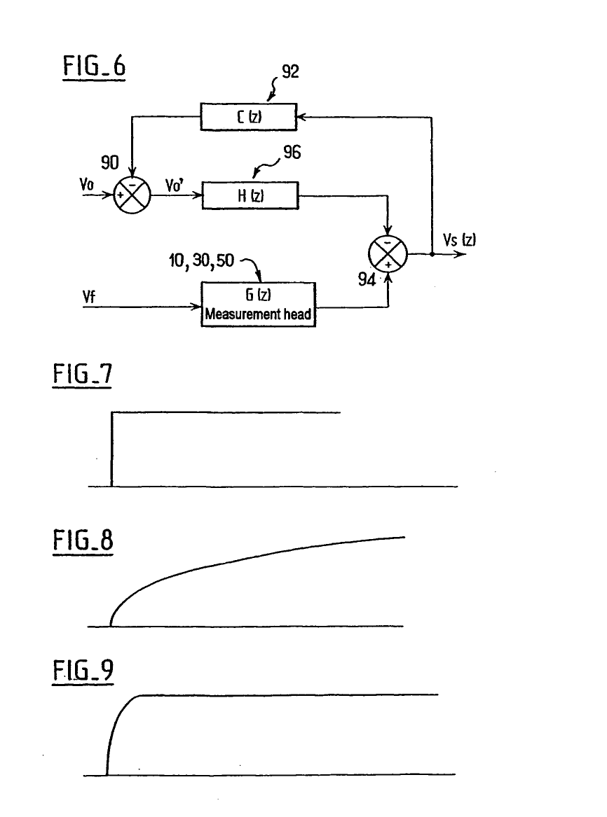

FIG. 6 diagrammatically represents a slaving of the offset correction carried out within the framework of the present invention,

FIGS. 7 to 9 diagrammatically represent an abrupt variation in capacitance between a measurement probe and a reference probe, the conventional response obtained with a known measurement device in accordance with document WO-0025098, and the response obtained with a device in accordance with the present invention utilizing a slaving of the offset correction

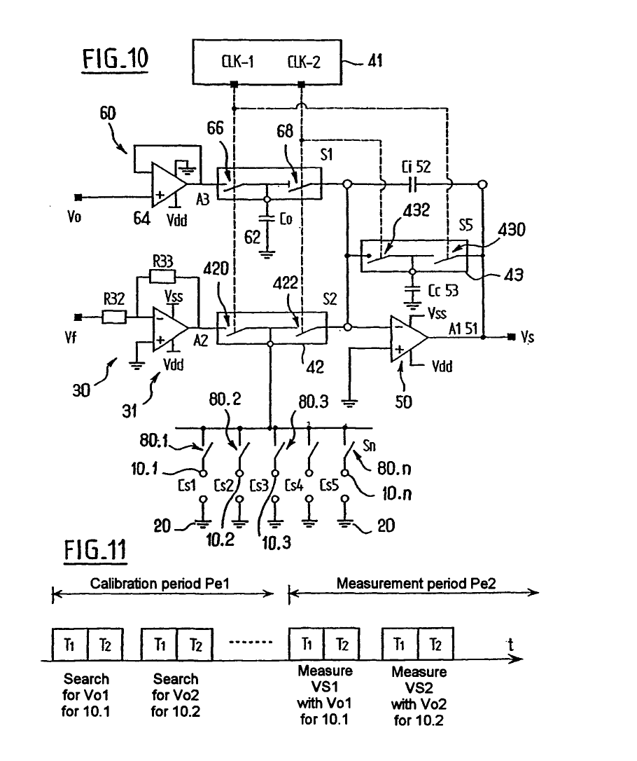

FIG. 10 represents a device in accordance with the present invention comprising several measurement heads,

FIG. 11 represents a timing chart of the operation of the device in accordance with the present invention comprising several measurement heads,

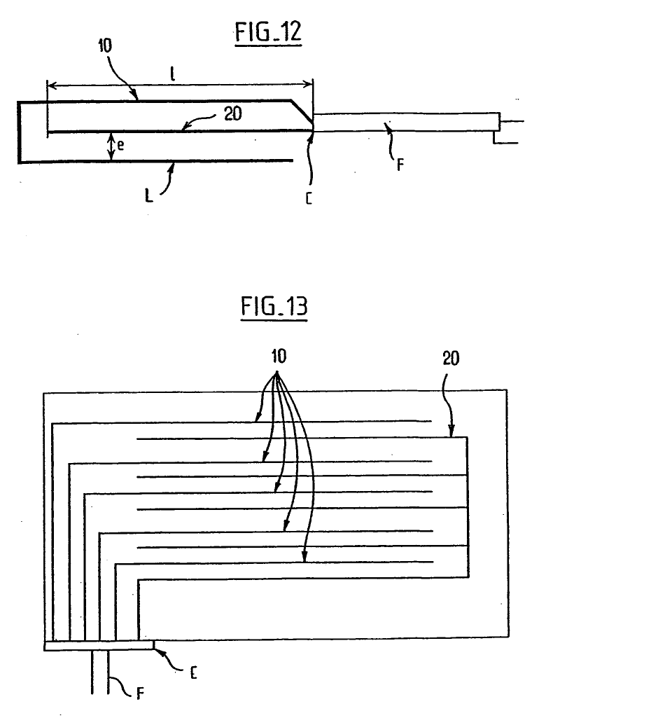

FIGS. 12, 13 and 14 diagrammatically represent three probe variants in accordance with the invention,

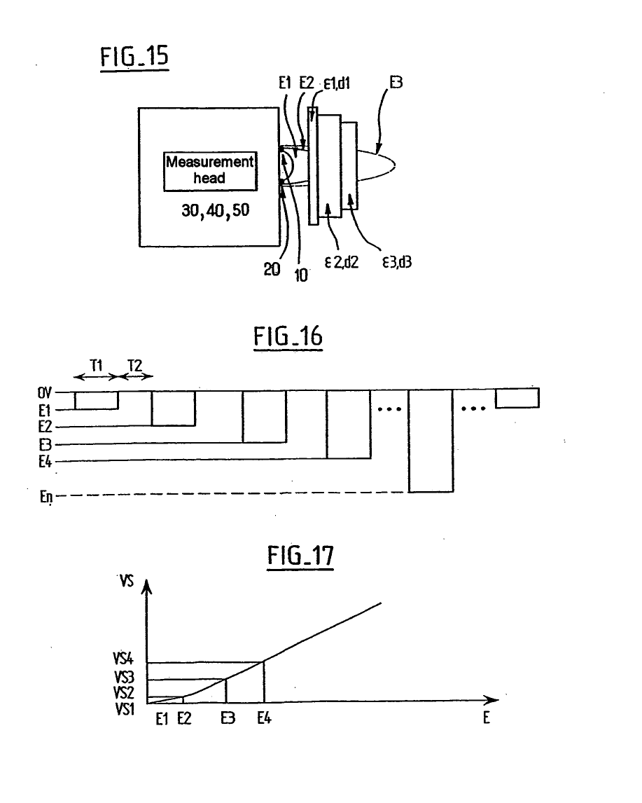

FIG. 15 diagrammatically represents the detection schematic of a measurement head in accordance with the present invention according to the amplitude of the supply voltage applied,

FIG. 16 diagrammatically represents a timing chart of the operation of the device in accordance with the present invention, and

FIG. 17 diagrammatically represents the voltages applied to the measurement probe, within the framework of a variant of the present invention, and the corresponding output voltages obtained.

FIG. 2 is the basic circuit dubbed the “measurement head” within the framework of the present invention, comprising a measurement probe 10 defining in combination with a reference element 20, a capacitance Cs, supply means 30, an electric charge integrator stage 50 and a time base 41.

Within the framework of the present invention, the reference element 20 may be formed of a reference probe or else of a mass consisting for example of the earth or a neighboring metal mass, for example the chassis of a motor vehicle.

The electrical supply means 30 here consist of a potential-inverter stage. This stage comprises an operational amplifier 31 whose noninverting input is grounded. The inverting input of the operational amplifier 31 receives a supply voltage Vf=+E by way of a resistor R32. A feedback resistor R33, preferably of the same value as R32, is arranged in feedback mode between the inverting input of the operational amplifier OP31 and its output.

The output of the operational amplifier OP31 is applied sequentially to the measurement probe 10 by way of an on/off switch 420 driven by the time base 41.

The reference probe 20 is grounded.

The measurement probe 10 is moreover linked sequentially to the inverting input of an operational amplifier 51 belonging to the integrator stage 50 by way of a second on/off switch 422 driven in opposition to the on/off switch 420 by the time base 41.

The two on/off switches 420, 422 constitute the inverting on/off switch 42 shown diagrammatically in FIG. 1.

Shown diagrammatically in FIG. 2 as CLK1 and CLK2 are the two phase opposition signals driving the two on/off switches 420, 422.

The noninverting input of the operational amplifier 50 is grounded.

The integration capacitor C52 is placed in feedback mode between the inverting input of the operational amplifier OP50 and its output.

The switched capacitor 53 has a first electrode which is grounded.

Its second electrode is linked sequentially to the output of the operational amplifier OP512 and to the latter's inverting input by two on/off switches 430, 432 driven in phase opposition by the signals CLK1 and CLK2 generated by the time base 41.

The two on/off switches 430, 432 constitute the on/off switch 43 shown diagrammatically in FIG. 1.

The time base 41 thus defines a sequence comprising two base periods T1, T2:

a period T1 during which the on/off switches 420 and 430 are closed, while the on/off switches 422 and 432 are open. During this first period the measurement probe 10 is charged to the supply voltage −E emanating from the stage 31, while the switching capacitor 53 is linked to the output of the integrator stage.

then the time base 41 defines a second period T2 during which the on/off switches 422 and 432 are closed, while the on/off switches 420 and 430 are open. In the course of this second period, the measurement probe 10 is linked to the inverting input of the operational amplifier OP51, while the switching capacitor 53 is linked to the input of the integrator stage 50.

Moreover the basic device illustrated in FIG. 2 comprises means 60 able to provide for an offset correction of the input of the integrator stage 50.

These offset correction means 60 are suitable for applying a correction voltage to the input of the integrator stage 50, this voltage compensating for the offset voltage liable to be generated at the input of the integrator stage, for example following a drift in temperature, following humidity, or following low-frequency electrical disturbances generated by capacitive coupling.

According to the particular embodiment illustrated in FIG. 2, the offset correction means 60 comprise a capacitor 62 associated with an operational amplifier 64.

The operational amplifier 64 is arranged in follower mode. On its noninverting input it receives a variable supply voltage V0. Its inverting input is arranged in feedback mode with its output. The output of the operational amplifier OP64 is linked sequentially at the tempo of the clock CLK1, by way of an on/off switch 66, to the capacitor 62. Furthermore, the capacitor 62 is itself applied sequentially at the tempo of the clock CLK2 generated by the time base 41, by way of a second on/off switch 68, to the input of the integrator stage 50, that is to say to the inverting input of the operational amplifier OP51.

The device illustrated in FIG. 2 thus delivers on the output of the operational amplifier 51 of the integrator stage 50 an output signal Vs=(Vf.Cs/Cc)(V0.C0/Cc), in which:

Vf designates the supply voltage at the input of the supply inverter stage 30,

V0 designates the supply voltage at the input of the offset correction stage 60,

Cs designates the capacitance defined between the measurement probe 10 and the reference probe 20,

C0 designates the capacitance of the capacitor 62 and

Cc designates the capacitance of the switching capacitor 53.

The offset correction means 60 illustrated in FIG. 2 makes it possible to inject an amount of charge Q0=V0.C0 onto the summation point of the amplifier 51 in a manner synchronous with the switching of the capacitance 53.

By adjusting the voltage V0 by any appropriate means, for example a digital analog converter, it is possible to bring the output voltage Vs practically to 0.

The device thus formed makes it possible to measure small variations in the capacitance Cs defined between the measurement probe 10 and the reference probe 20, including with a large offset of the probe, without saturating the integrator stage 51. Specifically, the measurement probe Cs can be split into two elementary capacitances Cs0 and Cm,

Cs0 designating the offset of the probe due to the connection wires, generally of high value, which may reach several hundred picofarads, and

Cm designating the variation in the virtual capacitance of the probe measuring the permittivity between the measurement probe 10 and the reference probe 20, generally a few hundred femtofarads.

The value of Cs0 may alter in particular as a function of the temperature and of the relative humidity. As its value is high with respect to Cm, the drifting thereof is amplified in the ratio ΔCs0/Cc, which is much greater than the full scale of the variation in Cm.

To avoid falsifying the measurement by saturation of the input stage, a differential stage (subtractor) 70 is used as mentioned previously, within the framework of the present invention.

On its two respective inputs this differential stage receives signals representative of the measurement head output for a similar offset correction but different controlled supply voltages.

Illustrated in the appended FIG. 3 is an exemplary embodiment of such a device in accordance with the present invention comprising a differential stage 70.

Depicted in this FIG. 3 are two measurement heads TE1 and TE2 each comprising a measurement probe 10 associated with an integrator stage 50, of the type illustrated in FIG. 2 described previously. Each measurement probe 10 is associated with electrical supply means 30 of the type illustrated in FIG. 2 and respective offset compensation means 60 of the type illustrated in FIG. 2.

The supply means 30 are designed to apply a specific controlled voltage En between each measurement probe 10 of a measurement head TE1 or TE2 and an associated reference element 20. Each reference element of a head TE1 or TE2 can be formed of a specific reference probe, or one which is common to both heads, or else of a mass consisting for example of the earth or a neighboring metal mass, for example the chassis of a motor vehicle. According to yet another variant the reference element 20 of a given head can be formed by the measurement probe 10 of the other head. In particular the reference element 20 of the measurement head TE1 can be formed by the measurement probe 10 of the reference head TE2.

On its respective inputs the differential stage 70 receives the output signals Vs1 and Vs2 emanating from the two measurement heads TE1 and TE2.

The device as a whole is driven by the time base 41.

The signal available at the output of the differential stage 70 can be utilized by any appropriate means, for example by a sample-and-hold device 72 followed by an analog digital converter 74 or any appropriate means of analysis, for example a microcomputer.

Shown diagrammatically in FIG. 3 under the references Cso1 and Cso2 are stray capacitances due in particular to the connection wires and liable to generate an offset voltage at the input of the integrator stages 50 of the measurement heads TE1 and TE2.

Moreover, shown diagrammatically in FIG. 3 under the reference P are disturbances by electrical coupling which are liable to be applied at the input of each measurement head TE1 and TE2.

The sequencer 41 illustrated in FIG. 3 controls a cyclic operation of the device comprising chiefly two successive cycles C1, C2 as illustrated in FIG. 4:

In the course of the first cycle C1 for calibrating the offset correction:

The device applies an identical input supply voltage Vf=E₀, preferably small, for example 1 volt, to the two heads TE1 and TE2.

During this cycle C1, the controller 74 adjusts the offset correction voltage Vo1 of the measurement head TE1 so as to obtain an output voltage Vs1 very close to 0, for example 0.1 volts.

During this same cycle C1, the controller 74 adjusts the offset correction voltage Vo2 applied to the second measurement head TE2 so as to obtain an output voltage Vs2 also very close to 0, for example 0.1 volts.

During this first cycle C1, the differential stage 70 delivers an output voltage Vs=Vs1−Vs2 very close to 0, equal to a voltage Vs.ref taken as reference.

During the second consecutive (measurement) cycle C2, the same offset correction voltage Vo1 as defined at the end of the first cycle, but a different supply voltage Vf=E₁, for example 5 volts, are applied to the measurement head TE1 by the controller 74.

During the second cycle C2, the same offset correction voltage Vo2 and the same supply voltage Vf=E₀ defined at the completion of the first cycle C1 are applied to the second measurement head TE2, serving as reference measurement head, by the controller 74.

If drifts occur, due for example to temperature or to relative humidity, they are present on the probes of the two measurement heads TE1 and TE2 because of their proximity and of their similarity of ambient medium.

The measurement being made differentially by virtue of the stage 70, a voltage Vs which dispenses with any drifts due to Cso1 and Cso2, i.e.:

Vsn=E1(Cso1/Cc−Cso2/Cc)(Co/Cc)(Vo1−Vo2)+(En−E1)(Cm/cc)

is obtained at the output of said stage.

If the two probes of the measurement heads TE1 and TE2 are sufficiently close to one another and if the two cycles are very closely spaced in time, for example at a frequency of 50 KHz, the common-mode noise due to capacitive coupling is also eliminated.

The device illustrated in FIG. 3 working in differential mode comprises two measurement heads TE1, TE2.

According to a variant embodiment in accordance with the present invention, it is possible to carry out a differential measurement, so as to maximize the signal/noise ratio, with a single measurement head. To do this, the device must comprise a storage means able to store the amplitude of the output signal from the measurement head for an offset correction and a given controlled supply voltage, so as subsequently to compare this signal with the signal obtained at the output of the measurement head for the same offset correction, but a different controlled voltage.

In such a variant a means comparable to the controller 74 defines two cycles C1, C2, as is illustrated in FIG. 5:

In a first cycle C1 (for calibrating the offset correction), a weak known electric field E₀, of for example 0 volts, is applied to the measurement probe 10 and the output signal Vs1 obtained is stored for a given offset correction Vo1, which output signal Vs1 corresponds to noise.

This output voltage Vs1 corresponding to noise is stored.

In a second cycle C2 (of measurement), a working electric field E₁ is applied, with the same offset correction Vo1, so as to obtain an output signal Vs2.

If the two measurements are sufficiently closely spaced in time, the ambient noise has not altered between two cycles.

It is then sufficient to proceed by differencing between the signal Vs1 stored at the end of the first cycle C1 and the signal Vs2 obtained in the course of the second cycle C2, to obtain a measurement result ridded of noise.

The aforesaid two cycles C1, C2 are repeated successively throughout the use of the device.

Whether the device utilizes two measurement heads TE1 and TE2 as illustrated in FIG. 3, or a single measurement head with storage of a signal Vs1, each of the aforesaid cycles C1, C2 itself comprises at least two successive sequences T1, T2, such as described previously, as has been illustrated in FIGS. 4 and 5.

Of course, the timing charts illustrated in FIGS. 4 and 5 may enjoy numerous variants.

Firstly for example, the calibration cycle C1 may comprise several sets of pairs of sequences T1, T2, if necessary, so as to adjust the offset corrections, before proceeding to a measurement cycle C2.

Furthermore, provision may be made for a regular alternation of a cycle C1 for calibrating the offset correction and of a measurement cycle C2, or else a periodic calibration cycle C1, for several consecutive measurement cycles C2.

Shown diagrammatically in FIG. 6 is a device in accordance with the present invention, in which the offset correction voltage is slaved to the output voltage from the integrator stage.

The functional diagram illustrated in FIG. 6 comprises a measurement head (formed by the probe 10, the supply means 30 receiving an input voltage Vf and the integrator stage 50) exhibiting a transfer function G(z), a first differentiator stage (subtracter) 90 which receives an offset correction voltage Vo on the one hand and on the other hand the output voltage Vs from the device, by way of a cell 92 having a transfer function C(z) and a second differentiator stage (subtracter) 94 which receives on the one hand the output from the measurement head and on the other hand the output Vo′ from the first differentiator stage 90, by way of a cell 96 having a transfer function H(z).

We have:

H(z)=Co/[C52+(C53−C52).z⁻¹]

G(z)=Cs/[C52+(C53−C52).z⁻¹] and

Vs(z)=Vf(z).G(z)−Vo′(z).H(z), i.e.

Vs(z)=Vf(z).G(z)−[Vo−Vs(z).C(z)]H(z).

From this we obtain: C(z)=C52/Co.

It is thus apparent that the stability and the response time of the system depend only on the ratio C52/Co. It is therefore sufficient to choose this ratio judiciously (as large as possible) to obtain a minimum response time, whilst preserving the integration term (which depends on C52), thereby making it possible to obtain a correct signal-to-noise ratio.

It will be noted in particular that the present invention which operates the slaving with regard to the offset correction voltage Vo, improves the stability of the system as compared with a slaving which were to be operated with regard to the input voltage Vf. Thus, specifically, the stability of the system depends only on ci and Co and in particular does not depend on Cs (virtual capacitance of the probe 10 which is variable).

Illustrated in FIG. 7 is the abrupt variation in capacitance Cs, in the form of a step, between the measurement probe 10 and a reference element 20.

A conventional device, in accordance with the state of the art illustrated in FIG. 1 and as described in the document WO-0025098, gives a slow response of the type illustrated in FIG. 8.

On the other hand, the device in accordance with the present invention, utilizing a slaving of the offset correction to the output signal Vs, makes it possible to obtain a fast response of the type illustrated in FIG. 9.

The person skilled in the art will appreciate that the device in accordance with the present invention makes it possible to reach, much faster than the known prior device, an output value representative of the actual value of the capacitance defined between the measurement probe 10 and the reference element 20.

The present invention allows a convergence time of less than 1 ms by correctly choosing Ci and Co.

A very short response time is appreciated in numerous applications. Mention will be made for example, and nonlimitingly, of the field of detection with a view to the control of inflatable airbags. Within this field in particular, it is indeed very important to have a very short response time, typically less than 10 ms.

FIG. 10 depicts a circuit in accordance with the present invention, comprising a series of measurement probes referenced 10.1 to 10.n defining in cooperation with a reference element 20, a respective capacitance Cs1, Cs2 . . . Csn, associated with supply means 30, an electric charge integrator stage 50 and a time base 41.

Each measurement probe 10 can be associated with a separate respective reference element 20. As a variant a reference element 20 can be common to several measurement probes 10, or even to all of them.

The supply means 30, the integrator stage 50 and the time base 41 are advantageously in accordance with the provisions defined previously with regard to FIG. 2.

As may be seen in FIG. 10, within the framework of the present invention, the measurement probes 10.1 to 10.n are linked successively, by way of on/off switches 80.1 to 80.n clocked by the time base 41, to the node defined between the on/off switches 420 and 422, so that these measurement probes 10.1 to 10.n are successively linked to the supply voltage Vf during the period T1 and to the inverting input of the operational amplifier 51 during the period T2.

The corresponding operational timing diagram is illustrated in FIG. 11.

This FIG. 11 depicts a first period Pe1 comprising a set of n pairs of two calibration sequences T1, T2, that is to say sequences for searching for the offset correction voltage V0, for each of the measurement probes 10 and a second period Pe2 also comprising a set of n pairs of two measurement periods T1, T2 for each measurement probe 10.

The sequences T1 and T2 are in accordance with the provisions described previously.

According to the illustration given in FIG. 3 the calibration periods Pe1 are grouped together and likewise the measurement periods Pe2 are grouped together.

As a variant, provision may be made to interpose the measurement periods Pe2 between the calibration periods Pe1.

Of course, the timing diagram shown in FIG. 11 must be combined with that of FIGS. 4 and 5 when the present invention utilizes in combination, a measurement in differential mode (based on two heads as shown diagrammatically in FIGS. 2 and 3, or based on a single head and with storage as shown diagrammatically in FIG. 4) and several measurement probes (as is shown diagrammatically in FIG. 10).

Illustrated in the appended FIG. 12 is a probe structure variant in accordance with the present invention, comprising a measurement probe 10 of “U” geometry flanking a reference probe 20, formed of a single strand.

This arrangement makes it possible, as compared with a more conventional device, in which the two probes 10 and 20 are formed of parallel single strands, to obtain a greater sensitivity of the order of 30 to 50%, since it sums the distribution of the fields between each of the two elements of the “U” measurement probe 10 and the reference probe 20 placed between them.

A similar advantage can be obtained by using in a symmetric manner a “U” reference probe 20 flanking a measurement probe 10, formed of a single strand.

By way of nonlimiting example, the following characteristics may be envisaged for the probes 10 and 20:

L=width of the probes 10 and 20 of the order of 0.5 mm to 5 mm (flat strip or wire),

l=length of the probes 10 and 20 equal to the zone to be detected

e=spacing between the probes 10 and 20 of the order of 5 to 40 mm depending on the desired detection distance,

E=thickness of the probe. Of the order of 0.5 mm to 5 mm for wire. From a few microns to 0.5 mm if the structure is a flat strip.

The probes 10 and 20 typically have a resistivity of the order of 0.1 to 100 ohms square and are preferably covered with a watertight material. This coating advantageously exhibits a high resistivity (R>100 Mohms) and a relatively low permittivity (Er<7).

Referenced C in FIG. 12 are the connections of the probes 10, 20 to a leaktight shielded cable F. The measurement probe is connected to the core of the shielded cable and the reference probe 20 to the shielding of the shielded cable.

The present invention can also benefit from the advantages of a U probe structure within the framework of the system with multiple probes, as is illustrated in FIG. 10.

For this purpose, it is sufficient to shape one at least of the reference element 20 and of the measurement probe 10, or both, into a U.

Represented for example in FIG. 13 is a system comprising several measurement probes 10 each consisting of a single strand, and associated with a common reference element 20 formed of a comb. The comb forming the reference element consists of multiple juxtaposed U elements which each flank a strand forming a measurement probe.

Referenced C in FIG. 13 is a connector providing on the one hand for the connections of the probes 10 to the conductors of a multistrand leaktight shielded cable F and on the other hand the connection of the reference element 20 to the shielding of this cable F. The measurement probe is connected to the core of the shielded cable and the reference probe 20 to the shielding of the shielded cable.

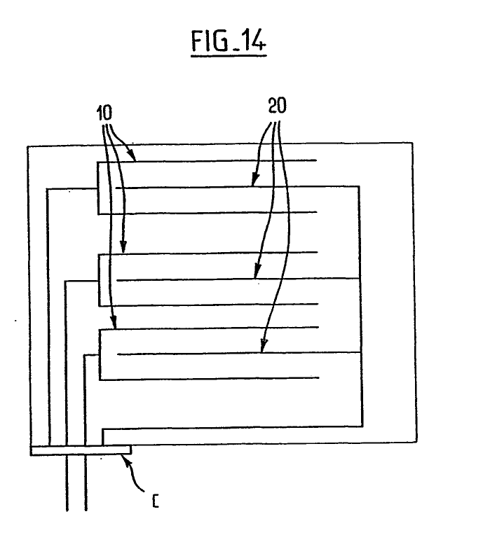

Illustrated in FIG. 14 is a variant according to which it is the measurement probes 10 which possess a U shape.

Such measurement probes 10 and associated reference element 20 may be provided on all appropriate supports, rigid or flexible, depending on the sought-after application.

According to the invention, to improve the measurement dynamic swing, the measurement head can receive successively, in the course of successive measurement cycles, on the measurement probe 10, variable voltages En.

These variable voltages En may for example be volt-wise successively increasing voltages, from 3 to 8 volts.

Nevertheless, in what follows, a variant will be alluded to, according to which two series of voltages respectively of low value and of high value are applied successively, so as to allow discrimination between a near mode of detection and a far mode of detection, and thus to allow possible correction of the measurements.

A value Vsn corresponding to a supply voltage En is obtained at the output of the measurement head, that is to say at the output of the integrator 51, at each measurement cycle.

To each supply voltage value En there corresponds an isopotential distribution line which closes up in space, with respect to the reference probe 20, or even with respect to a neighboring metal mass, for example the chassis of a motor vehicle, in the case of such an application, or else with respect to the earth.

The larger the value of the supply voltage En, the larger the range of the equipotential line, as illustrated in FIG. 15.

The person skilled in the art will understand that the value of the capacitance thus detected between the measurement probe 10 and the reference probe 20 by integration of the electric charge tapped off from the measurement probe 10, depends directly on the permittivity of the medium influencing the detection diagram of the measurement head, and of course depends on the thickness of this medium.

By way of nonlimiting example, within the context of the detecting of a user on a motor vehicle seat, in particular for authorizing or otherwise the deployment of a protection airbag, the present invention makes it possible by analyzing the alterations in the signals at the output of the integrator stage 51 of the measurement head to discriminate, as a function of the detection diagram involved, between the presence of a human body and an allied stray phenomenon, such as the presence of moisture on the seat.

The relative permittivity of a human body being of the order of 80 times greater than the permittivity of materials involved in the making of a motor vehicle seat and of its surroundings, the analysis of the output signals from the measurement head actually makes it possible to guarantee the detection of presence of a person near the measurement probe 10 and also to pinpoint his position with respect to the latter.

Shown diagrammatically in FIG. 16 is the increasing trend of the supply voltage, for example between E1, E2, E3, E4 . . . during the periods T1 of the sequencing, the periods T2 illustrated in FIG. 16 corresponding to the periods of linking of the measurement probe 10 to the inverting input of the operational amplifier 51 and simultaneously to the linking of the switching capacitor 53 onto this same inverting input. Of course, at the end of the cycle of increase from E1 to En, a similar measurement cycle is repeated.

As indicated previously, according to a variant of the present invention, two series of voltages of respectively low value and high value, for example two voltages E1 and E2 of low value for a detection in near mode and two voltages E3 and E4 of high value for a detection in far mode, are applied successively to the measurement probe 10, as shown diagrammatically in FIG. 17.

Such a process makes it possible in particular to take account of the presence of certain disturbing media or bodies, close to the measurement probe 10, in the detection of more remote bodies.

To each value of En there corresponds a value Vsn which is stored.

One therefore obtains a series of pairs of values Vsn/En.

On the basis of these data, the means of analysis of the device can calculate indirectly the value of the virtual capacitance defined between the measurement probe 10 and the reference element 20, respectively in near mode, i.e. Csnear, and in far mode, i.e. Csfar.

The virtual capacitance detected in far mode Csfar, may be determined through the relation:

Csfar=Cc.K1=Cc(Vs4−Vs3)/(E4−E3)

in which Cc designates the capacitance of the switching capacitor 53.

This capacitance Csfar conveys for example, in the case of the detecting of a user in a motor vehicle seat, the distance from the user to the seat.

Likewise the virtual capacitance detected in near mode Csnear, may be determined through the relation:

Csnear=Cc.K2=Cc(Vs2−Vs1)/(E2−E1).

This capacitance Csnear conveys for example, in the case of a use for the detecting of a user in a vehicle seat, the possible presence of a disturbing body or obstacle, such as a bead mat or a towel, between the user and the seat.

In this last case (that is to say the presence of an obstacle), the value Csfar is affected and underrated.

It is possible to correct the resulting error in the distance expressed for the user, by correcting the value obtained for Csfar, on the basis of the value obtained for Csnear.

Various means of correction may be used.

According to an advantageous embodiment, the ratio K1/K2 is calculated and if this ratio is greater than 1, a corrected value of Csfar is calculated, i.e. Csfarmod on the basis of the relation:

Csfarmod=Csfar.K=Csfar.(K1/K2).

The value Csfarmod thus corrected gives a good approximation of the distance of the user involved in the definition of Vs3 and Vs4 under E3 and E4.

Quite obviously the timing diagram shown in FIG. 16 must be combined with that that of FIG. 11 and/or that of FIGS. 4 and 5 when the present invention utilizes in combination, variable supply voltages and a differential measurement (based on two heads as is shown diagrammatically in FIGS. 2 and 3, or on the basis of a single head and with storage as is shown diagrammatically in FIG. 4) and/or several measurement probes (as is shown diagrammatically in FIG. 10).

Of course the present invention is not limited to the particular embodiments just described but extends to any variant in accordance with the spirit thereof.

The present invention can relate to a large number of applications. The detection of presence of a user on a motor vehicle seat was alluded to previously, in particular in respect of the control of an inflatable airbag system. However, the present invention is not limited to this particular application. The present invention can for example relate also, among other things, to the fields of anti-intrusion detection or fluid level detectors.

1. A measurement device comprising at least one measurement head including at least one measurement probe (10), means (30) able sequentially to apply a controlled supply voltage between the measurement probe (10) and a reference element (20) and means (50) able to integrate the electric charge accumulated on the measurement probe (10), characterized in that it furthermore comprises means (60) able to provide an offset correction of the input of the integrator stage (50).

2. The device as claimed in claim 1, characterized in that it furthermore comprises a differentiator stage (70) receiving on its respective inputs signals representative of the measurement head output for a similar offset correction, but different controlled supply voltages.

3. The device as claimed in one of claims 1 or 2, characterized in that it comprises two electrically conducting bodies respectively constituting a measurement probe (10) and a reference element (20), electrical supply means (30) able to deliver a DC electric voltage of controlled amplitude, an integrator stage (50) comprising a capacitance switching system (53) and operating means (40) suitable for defining cyclically, at a controlled frequency, a set of two sequences (T1, T2): a first sequence in the course of which the electrical supply means (30) are linked to the measurement probe (10) so as to apply an electric field between the measurement probe (10) and the reference element (20) and accumulate electric charge on the measurement probe (10), then a second sequence in the course of which the electrical supply means (30) are disconnected from the measurement probe (10) and the latter is linked to a summation point of the integrator stage (50) so as to transfer charge into the integrator stage (50) and obtain at the output of the latter a signal representative of the permittivity existing between the measurement probe (10) and the reference element (20), the integrator stage (50) furthermore comprising an operational amplifier (51), a first integration capacitor (52) arranged in feedback mode with this amplifier (51) and a second capacitor (53) switched between the output and the input of the operational amplifier (51) at the tempo of the sequences (T1, T2) driven by operating means (40), so that in the steady balance state, there is obtained at the output of the operational amplifier (51), a voltage “Vs balance” equal to:
Ecs/C53, in which relation −E designates the amplitude of the voltage across the terminals of the electrical supply means (30), and Cs and C53 respectively designate the values of the capacitances defined between the measurement probe (10) and the reference element on the one hand and the second switched capacitor (53) on the other hand.

4. The device as claimed in one of claims 1 to 3, characterized in that it comprises two measurement heads (TE1 and TE2), and the signals applied to the differential stage (70) originate respectively from the output of the integrator stages (50) of these two measurement heads.

5. The device as claimed in claim 4, characterized in that the two measurement probes are in tight proximity and placed in the same medium.

6. The device as claimed in one of claims 4 or 5, characterized in that it comprises a controller able to apply a cyclic manner of operation comprising two successive cycles: a first cycle in the course of which the two measurement heads receive similar supply voltages Vf and the offset voltage is corrected, and a second cycle in the course of which the supply voltage on one of the measurement heads TE1 is modified, while the supply voltage on the second measurement head TE2 and the offset voltages previously obtained are maintained.

7. The device as claimed in one of claims 1 to 4, characterized in that it comprises a single measurement head and means able to store the output signal from the measurement head for an offset correction and a given controlled supply voltage, so as to compare this stored voltage with that obtained at the output of the measurement head for the same offset correction, but a different controlled supply voltage.

8. The device as claimed in one of claims 1 to 7, characterized in that the offset correction means (60) comprise a capacitor (62) supplied via an adjustable voltage Vo.

9. The device as claimed in one of claims 1 to 9, taken in combination with claim 3, characterized in that it comprises several cycles C1, each comprising a pair of two sequences (T1, T2) for a calibration of the offset correction before a measurement cycle C2.

10. The device as claimed in one of claims 1 to 9, taken in combination with claim 3, characterized in that it comprises several measurement cycles C2, consecutive with a cycle C1 for calibrating the offset correction.

11. The device as claimed in one of claims 1 to 10, taken in combination with claim 3, characterized in that each offset correction calibration cycle C1 and each measurement cycle C2 comprises at least one set of two sequences (T1, T2).

12. The device as claimed in one of claims 1 to 11, characterized in that one at least of the measurement probe (10) or of the reference element (20) has a “U” geometry.

13. The device as claimed in claim 12, characterized in that the measurement probe (10) has a “U” geometry.

14. The device as claimed in claim 12, characterized in that the reference element (20) has a “U” geometry.

15. The device as claimed in one of claims 12 to 14, characterized in that it comprises a reference element (20) common to several measurement probes.

16. The device as claimed in claim 15, characterized in that it comprises a comb reference element (20).

17. The device as claimed in one of claims 1 to 16, characterized in that it furthermore comprises means able to slave the offset correction to the output signal from the integrator stage.

18. The device as claimed in claim 17 taken in combination with claim 3, characterized in that the slaving means (C(z)) possess a C52/Co transfer function, C52 designating the integration capacitor, while Co designates the capacitor used for the offset correction voltage.

19. The device as claimed in one of claims 1 to 18, characterized in that it comprises means able to place different respective probes (10.1, 10.n) successively in circuit on the input of the integrator stage.

20. A measurement device comprising at least one measurement head comprising at least one measurement probe (10), means (30) able sequentially to apply a controlled supply voltage between the measurement probe (10) and a reference element (20) and means (50) able to integrate the electric charge accumulated on the measurement probe (10), characterized in that it comprises means able to place different respective probes (10.1, 10.n) successively in circuit on the input of the integrator stage.

21. The device as claimed in one of claims 19 or 20, characterized in that it comprises a network of on/off switches (80.1, 80.n) which are designed to provide the successive linking of the probes to the input of the integrator stage (50).

22. The device as claimed in one of claims 19 to 21, characterized in that it comprises means able to define a tick rate comprising a first period (Pe1) comprising a set of n pairs of two calibration sequences (T1, T2), during which the analysis means search for the offset correction voltage (V0), for each of the measurement probes (10) and a second period (Pe2) also comprising a set of n pairs of two measurement sequences (T1, T2) respectively for each measurement probe (10).

23. The device as claimed in one of claims 1 to 22, characterized in that it comprises means able to place n different respective probes (10.1, 10.n) successively in circuit on the input of the integrator stage, and means able to define a tick rate comprising a first period (Pe1) comprising a set of n pairs of two calibration sequences (T1, T2), during which the analysis means search for the offset correction voltage (V0), for each of the measurement probes (10) and a second period (Pe2) also comprising a set of n pairs of two measurement sequences (T1, T2) respectively for each measurement probe (10), during the second period, a differentiator stage (70) receiving on its respective inputs two signals representative of a measurement head output for a similar offset correction, but different controlled supply voltages.

24. The device as claimed in one of claims 22 or 23, characterized in that in the course of each pair of two successive sequences, respectively a controlled voltage is applied to a measurement probe (10), then the measurement probe (10) is linked to the input of the integrator stage (50).

25. The device as claimed in one of claims 1 to 26, characterized in that the electrical supply means (30) are suitable for applying successive controlled variable voltages (E1, E2 . . . ) to the measurement probe (10) and that the device furthermore comprises means for analyzing the trend of the signals at the output of the integrator stage as a function of the supply voltages applied.

26. A measurement device comprising at least one measurement head comprising at least one measurement probe (10), means (30) able sequentially to apply a controlled supply voltage between the measurement probe (10) and a reference element (20) and means (50) able to integrate the electric charge accumulated on the measurement probe (10), characterized in that the electrical supply means (30) are suitable for applying successive controlled variable voltages (E1, E2 . . . ) to the measurement probe (10) and that the device furthermore comprises means for analyzing the trend of the signals at the output of the integrator stage as a function of the supply voltages applied.

27. The device as claimed in one of claims 1 to 26, characterized in that the reference element is formed of a reference probe (20).

28. The device as claimed in one of claims 1 to 27, characterized in that the reference element (20) is formed of a mass consisting for example of the earth or a neighboring metal mass, for example the chassis of a motor vehicle.

29. The device as claimed in one of claims 25 or 26, characterized in that the supply voltage increments are constant.

30. The device as claimed in one of claims 25, 26 or 29, characterized in that the voltage increments are of the order of 1 volt.

31. The device as claimed in one of claims 25, 26, 29 or 30, characterized in that the electrical supply means are suitable for applying at least two series of voltages of respectively low value and high value successively to the measurement probe (10).

32. The device as claimed in one of claims 25, 26, 29 to 31, characterized in that the electrical supply means are suitable for applying successively to the measurement probe (10) at least two voltages E1 and E2 of low value for a detection in near mode and two voltages E3 and E4 of high value for a detection in far mode.

33. The device as claimed in claim 32, characterized in that the means of analysis are suitable for calculating a virtual capacitance in far mode Csfar, proportional to K1=(Vs4−Vs3)/(E4−E3) and a virtual capacitance in near mode Csnear, proportional to K2=(Vs2−Vs1)/(E2−E1), in which relations Vsn designates the voltage obtained at the output of the integrator stage for a supply voltage En.

34. The device as claimed in one of claims 25, 26, 29 to 33, characterized in that the analysis means are suitable for correcting a value Csfar obtained in far mode with voltages of high value, on the basis of a value Csnear obtained in near mode for voltages of low value.

35. The device as claimed in one of claims 33 to 34, characterized in that the analysis means are suitable for calculating the ratio K1/K2, and if this ratio is greater than 1, calculating a corrected value of the virtual capacitance in far mode Csfar, i.e. Csfarmod on the basis of the relation:
Csfarmod=Csfar.K=Csfar. (K1/K2).

36. The device as claimed in one of claims 25, 26, 29 to 35, characterized in that it comprises means able to control a manner of operation in the form of successive cycles in the course of which, from one cycle to another, the voltage applied to the measurement probe (10) alters in a controlled manner, each cycle being divided into two successive sequences (T1, T2) in the course of which respectively the controlled voltage is applied to the measurement probe (10), then the measurement probe (10) is linked to the input of the integrator stage (50).
